(19) United States
(12) Patent Application Publication
(10) Pub. No.: US 2003/0064579 A1
(43) Pub. Date: Apr. 3, 2003

(54) Surface protecting adhesive film for semiconductor wafer and protecting method for semiconductor wafer using said adhesive film

(76) Inventors: Masafumi Miyakawa, Aichi (JP); Makoto Kataoka, Aichi (JP); Yasuhisa Fujii, Chiba (JP); Yoshihisa Saimoto, Aichi (JP); Shinichi Hayakawa, Aichi (JP)

Correspondence Address: Robert G. Mukai, BURNS, DOANE, SWECKER & MATHIS, L.L.P., P.O. Box 1404, Alexandria, VA, 22313-1404, US

(21) Appl. No.: 10/247,354

(22) Filed: Sep. 20, 2002

(30) Foreign Application Priority Data
Sep. 27, 2001 (JP) 2001-295454

(51) Int. Cl. H01L 21/4763

(52) U.S. Cl. 438/628; 438/643

(57) ABSTRACT

An object of the present invention is to provide a surface protecting adhesive film for a semiconductor wafer having excellent adhesive properties, breakage resistance and stain resistance. According to the invention, provided is a surface protecting adhesive film for a semiconductor wafer in which at least one layer of an intermediate layer and an adhesive layer are provided on one surface of a base film, a minimum value (G′ min) of storage elastic modulus of an adhesive layer (B) at from 50° C. to 100° C. is from 0.07 MPa to 5 MPa, storage elastic modulus of at least one layer (C) of the intermediate layer at 50° C. is from 0.001 MPa to less than 0.07 MPa and thickness (tb, unit: μm) of the adhesive layer (B) and total thickness (tc, unit: μm) of the intermediate layer (C) having said storage elastic modulus satisfy a relation represented by the following mathematical expression (1):

tc≧3tb (1)

### BACKGROUND OF THE INVENTION

1. Field of the Invention

The present invention relates to surface protecting adhesive films for semiconductor wafers and protecting methods for semiconductor wafers using the adhesive films. More particularly, the present invention relates to a surface protecting adhesive film for a semiconductor wafer which is adhered via an adhesive layer to a surface of a semiconductor wafer in a side in which an integrated circuit is embedded (hereinafter referred to also as wafer surface; surface of wafer), when a surface of a semiconductor wafer in a side in which an integrated circuit is not embedded (hereinafter referred to also as wafer reverse side; reverse side of wafer) is ground in order to avoid breakage or stain of a semiconductor wafer at a production step of a semiconductor integrated circuit, and a protecting method for a semiconductor wafer using the adhesive film.

2. Description of the Related Art

A semiconductor device is ordinarily produced by a method in which high purity silicon monocrystal or the like is sliced to produce a wafer and, then, an integrated circuit is embedded in the thus-produced wafer by ion implantation, etching or the like and, thereafter, the wafer thus embedded with the integrated circuit is subjected to reverse-side grinding processing in which a reverse side of the wafer is mechanically ground by means of grinding, lapping, polishing or the like to allow it to be as thin as from about 100 μm to about 600 μm and, subsequently, the thus-ground wafer is subject to dicing processing to produce a chip. When a thickness of the wafer is decreased to be as low as from 200 μm to 250 μm, in order to enhance strength of the wafer by removing a damaged layer caused on the reverse side thereof by mechanical grinding, a step of executing a chemical treatment on the reverse side may sometimes be performed subsequent to such a reverse-side grinding step. Ordinarily, in order to avoid breakage or stain of the semiconductor wafer in steps as described above, a surface protecting adhesive film for a semiconductor wafer has been used.

Specifically, a surface protecting adhesive film for a semiconductor wafer is adhered to a wafer surface via an adhesive layer thereof to protect the wafer surface and, then, a reverse side of the wafer is mechanically ground. After such grinding, a chemical treatment step may optionally be performed on the reverse side of the wafer. After these steps are completed, the adhesive film is peeled away from the wafer surface.

As the surface protecting adhesive film for the semiconductor wafer as described above, for example, a film for processing a wafer characterized in that an adhesive layer is provided on a surface of a substrate sheet having a Shore hardness D of 40 or less is disclosed in Japanese Patent Laid-Open No. 10242/1986. As an important performance expected for such a surface protecting adhesive film for a semiconductor wafer as described above, mentioned is adhesiveness to an uneven wafer surface. The adhesiveness to the uneven wafer surface is particularly important from the standpoint of prevention of breakage of the wafer and suppression of inplane thickness variation (hereinafter referred to also as TTV in short) of the wafer after having been ground. In fact, on a surface of an ordinary semiconductor wafer, there exists unevenness caused by an integrated circuit device embedded therein or a passivation layer formed on the integrated circuit. In order not only to prevent the wafer from being broken during grinding by relaxing grinding stress at the time of grinding the reverse side thereof but also to perform grinding without deteriorating thickness accuracy of the wafer subjected to reverse side grinding, it is necessary to allow the protecting adhesive film for the semiconductor wafer to be sufficiently adhered to the uneven surface thereof thereby absorbing such unevenness.

Heretofore, there has been a case in which the unevenness of maximum 20 μm derived from a coating layer made of polyimide or the like, a vapor deposited film such as a silicon oxide film, a silicon nitride film or the like, a scribing line or the like is present on the surface of the ordinary semiconductor wafer. However, such unevenness as described above has a dent of only about 10% of a total surface area of the semiconductor wafer such that a top of a projected portion which occupies most of the surface area thereof is flat. Ordinarily, an area of the relatively flat projected portion occupies about 90% of the total surface area of the semiconductor wafer. It has been possible to protect the surface of the wafer having such unevenness as described above by using the above-described surface protecting adhesive film for the semiconductor wafer and respond to the unevenness without causing breakage or stain of the wafer.

However, in recent years, with an advent of technical innovation in the semiconductor industry, a wafer having a surface contour which is hardly responded by the ordinary surface protecting adhesive film for the semiconductor wafer has appeared. For example, with an improvement of packaging technique and enhancement of performance of the integrated circuit, a packaging method referred to as flip chip packaging in which a surface of a semiconductor integrated circuit is turned over such that it is located downside and, then, connected to a substrate has increasingly been adopted. As a wafer having a chip suitable for such a packaging method or the like, a semiconductor wafer having a bump electrode in projected form has come to be produced. A material of the bump electrode is solder, gold, silver, copper or the like; a shape thereof is of a ball form, a columnar form, a square form or the like. The bump electrode is formed such that it is projected from the surface of the wafer. Height thereof (difference of height between a wafer surface and a top of the bump electrode) is ordinarily from 10 μm to 150 μm and sometimes 200 μm. Further, with diversification of production processes of semiconductor chips, a process in which, before the reverse side of the semiconductor wafer is ground, chips on the surface of the semiconductor wafer are inspected and, then, a defect chip is provided with a defect circuit identification mark (referred to also as ink dot) in a projected form having a height of from 10 μm to 100 μm and, thereafter, reverse side grinding of the semiconductor wafer is performed has increasingly been adopted.

When the ordinary surface protecting adhesive film for the semiconductor wafer is adhered to a wafer surface having a projection such as a bump electrode or a defect circuit identification mark or the like for protecting it, the adhesive film can not sufficiently follow the projection thereby causing an insufficient adhesion of the adhesive film to a projected portion derived from the projection and, accordingly, stress at the time of grinding is centered in the projection thereby sometimes breaking the wafer during grinding processing. Further, even when the wafer is not broken, a portion of the reverse side of the wafer corresponding to the projection on the surface is forced to be ground deeper than surrounding portions thereof by being affected by the projection to generate a dent referred to as a dimple or the like whereupon TTV of the wafer subjected to grinding processing is deteriorated to give an adverse effect to a subsequent step such as dicing or the like or to cause a defect in products. In some cases, a serious problem in which a crack is generated starting from the dimple to completely damage the wafer has occurred.

As a method to solve the problems, for example, Japanese Patent Laid-Open No. 189504/1998 discloses a method for grinding a reverse side of a semiconductor wafer having a bump height (A) of from 10 μm to 100 μm. A point of the method is to use an adhesive film in which a base film constructing the adhesive film having a Shore hardness D of 40 or less is used, and thickness (B) thereof, thickness (C) of an adhesive layer and the above-described bump height (A) satisfy relations of 4A≦B and 0.6A≦C. Even when the semiconductor wafer has the bump height of about 100 μm, the reverse side grinding can be performed without generating breakage of the wafer, stain on the surface thereof or the like so that this method can be said as being an excellent method.

However, in recent years, there has been an increasing tendency for miniaturization and weight saving of the semiconductor circuit and, accordingly, cases in which a greater number of pins and finer pitches have been adopted are increasing in number. As a result of adoption of the finer pitches, for example, when a solder ball bump electrode having a height of about 100 μm is provided on the wafer surface, less than 300 μm of a pitch is most prevailing at present whereas about 500 μm of the pitch was ordinarily prevailing in the past. Further, a wafer having even about 200 μm of pitch has appeared.

When a ordinary surface protecting adhesive film for reverse-side grinding of the semiconductor wafer is used to the wafer having a fine-pitched bump electrode, at the time of peeling the adhesive film away from the wafer subjected to grinding processing, a portion of adhesive is likely to remain on the wafer surface (hereinafter referred to also as adhesive residue) to sometimes stain the wafer surface. It is considered that this happens because, when the adhesive film is peeled away from the wafer surface on which a projection of a bump electrode or the like is present, a complicated force caused by the presence of the projection acts on the adhesive in the periphery of the projection. When the adhesive residue is generated on the wafer surface after the adhesive film is peeled away, such generation of the adhesive residue causes a serious problem such as an electrical failure of the integrated circuit, delamination of a mold resin at the time of packaging or the like which leads to aggravation of a yield rate of a semiconductor chip.

Particularly, when the wafer having the fine-pitched bump electrode on the surface thereof is used, there is a tendency in which the adhesive entered in a small gap between any two adjacent bump electrodes is likely to be cut and remain therein thereby generating a serious problem. There is a case in which such an adhesive residue problem relative to the fine-pitched bump electrodes can not be solved by the reverse side grinding method of the semiconductor wafer disclosed by the above-described Japanese Patent Laid-Open No. 189504/1998. An advent of a technique capable of grinding such a wafer as described above without problem has strongly been required.

Further, Japanese Patent Laid-Open No. 203255/2001 discloses an adhesive sheet for use in holding a semiconductor wafer by adhering it to a surface of the semiconductor wafer at the time of processing the semiconductor wafer, wherein the adhesive sheet is an adhesive sheet for holding and protecting the semiconductor wafer in which an intermediate layer having an elastic modulus of from 30 kPa to 1000 kPa and a gel ratio of less than 20% is provided on one surface of a base layer and an adhesive layer is formed on a surface of the thus-provided intermediate layer. The above-described Japanese Patent Laid-Open also discloses that the elastic modulus of the adhesive layer can appropriately be determined, so long as it does not damage adhesiveness and a holding property, and is preferably from 10 kPa to 1000 kPa at 25° C. However, there is no description on temperature dependency of the adhesive layer and stain prevention of the wafer surface.

Under these circumstances, even in a case of a wafer having a projection such as a fine-pitched bump electrode, a defect circuit identification mark or the like on a surface thereof, a surface protecting adhesive film for a semiconductor wafer which can sufficiently be adhered to the projection to prevent the wafer from being broken or a dimple from being generated and be used without generating adhesive residue on the surface thereof has been required.

### SUMMARY OF THE INVENTION

Under these circumstances, an object of the present invention is to provide a surface protecting adhesive film for a semiconductor wafer that has an excellent adhesiveness to a projection even in a wafer which has a fine-pitched projection, is hard to be adhered and likely to generate an adhesive residue on a surface thereof, that does not generate a crack or a dimple, is capable of being ground and, at the same time, has an excellent stain resistance such that no adhesive residue is generated on a wafer surface after the adhesive film is peeled away therefrom, as well as a protecting method for the semiconductor wafer using the above-described surface protecting adhesive film for the semiconductor wafer.

The present inventors have conducted an extensive study and, as a result, have found that a surface protecting adhesive film for a semiconductor wafer in which at least one layer of an intermediate layer having a specified storage elastic modulus and an adhesive layer are provided on one surface of a base film, storage elastic modulus of the adhesive layer in an outer side is set higher whereas storage elastic modulus of at least one layer of the intermediate layer in an inner side is set lower and thickness of these layers is in a specified relation therebetween to achieve the present invention.

Namely, according to one aspect of the present invention, there is provided a surface protecting adhesive film for a semiconductor wafer in which at least one layer of an intermediate layer and an adhesive layer are provided on one surface of a base film, a minimum value (G′ min) of storage elastic modulus of an adhesive layer (B) at from 50° C. to 100° C. is from 0.07 MPa to 5 MPa, storage elastic modulus of at least one layer (C) of the intermediate layer at 50° C. is from 0.001 MPa to less than 0.07 MPa and thickness (tb, unit: μm) of the adhesive layer (B) and total thickness (tc, unit: μm) of the intermediate layer (C) having said storage elastic modulus satisfy a relation represented by the following mathematical expression (1):

tc≧3tb (1)

As a preferred embodiment of the surface protecting adhesive film for the semiconductor wafer according to the present invention, mentioned is the above-described surface protecting adhesive film for the semiconductor wafer in which storage elastic modulus (G′ 25° C.) of the adhesive layer (B) at 25° C. is from 0.1 MPa to 5 MPa and storage elastic modulus ratio (G′ 25° C./G′ min) is in a range of from 1 to 3.

Further, according to another aspect of the present invention, there is provided a protecting method for a semiconductor wafer comprising the steps of:

applying a surface protecting adhesive film for the semiconductor wafer on a circuit-forming surface of the semiconductor wafer;

grinding a reverse side of the semiconductor wafer; and

peeling the surface protecting adhesive film for the semiconductor wafer away,

wherein the above described surface protecting film for the semiconductor wafer is used as the surface protecting adhesive film for the semiconductor wafer.

Characteristics of the surface protecting adhesive film for the semiconductor wafer according to the present invention are in that at least one layer of the intermediate layer is formed on one surface of the base film and, further, the adhesive layer is formed in an outside of the thus-formed layer and, furthermore, storage elastic modulus of the outermost adhesive layer (B) is set to be high whereas storage elastic modulus of at least one layer (C) of the intermediate layer is set low and, still further, the thickness (tb) of the adhesive layer (B) and the total thickness of the intermediate layer (C) in which storage elastic modulus is set to be low satisfy a relation represented by the above-described mathematical expression (1).

Characteristics of a preferred embodiment of the surface protecting adhesive film for the semiconductor wafer are in that storage elastic modulus ratio (G′ 25° C./G′ min) of the adhesive layer (B) is defined in a range of from 1 to 3. In other words, it is characteristic that, taking prevention of any stain on a surface of a semiconductor wafer to be caused by the adhesive layer (B) into consideration, an index denoting temperature dependence of the storage elastic modulus of the adhesive layer (B) is defined in a narrow range.

By adopting the above-described arrangements, even when any projection is present on a surface of a semiconductor wafer, an excellent adhesiveness to the surface of the semiconductor wafer is achieved whereupon any wafer breakage or dimple generation at the time of grinding a reverse side of the wafer can be prevented. Further, adhesive residue is not found on the wafer surface from which the adhesive film has been peeled away thereby allowing an excellent stain resistance to be attained at the same time.

Specifically, the adhesive layer (B) located apart farthermost from the base film is a layer which directly contacts the wafer surface in a state that the adhesive film is applied to the wafer surface whereupon, by defining a minimum value of the storage elastic modulus at from 50° C. to 100° C. in a relatively high range of from 0.07 MPa to 5 MPa, generation of the adhesive residue on the wafer surface at the time of peeling the adhesive film away from the wafer surface can be prevented and, further, by defining the storage elastic modulus of the intermediate layer (C) at 50° C. to be in a relatively low range of from 0.001 MPa to less than 0.07 MPa and, still further, by satisfying the relation represented by the above-described mathematical expression (1), and excellent adhesiveness to the projection present on the wafer surface is attained thereby preventing the wafer from being broken or the dimple from being generated thereon at the time of grinding the reverse side of the wafer. Still further, as a preferred embodiment, by defining both the storage elastic modulus (G′ 25° C.) at 25° C. and storage elastic modulus ratio, (G′ 25° C./G′ min) of the adhesive layer (B) to be appropriate values, the foregoing effects can more remarkably be exhibited.

Further, the storage elastic modulus according to the present invention is intended to mean a value measured by a method explained in an embodiment to be described below.

### DETAILED DESCRIPTION OF THE PREFERRED EMBODIMENTS

The present invention will now be described in detail. The present invention is a surface protecting adhesive film for a semiconductor wafer and a protecting method for a semiconductor wafer by using the surface protecting adhesive film for the semiconductor wafer.

Firstly, the semiconductor wafer to which the surface protecting adhesive film for the semiconductor wafer according to the present invention can be applied will be described. As semiconductor wafers to which the adhesive film according to the present invention are applicable, mentioned are not only a silicon wafer but also wafers made of, for example, germanium, gallium-arsenic, gallium-phosphor, gallium-arsenic-aluminum and the like.

An integrated circuit formed on a wafer surface is not limited to any particular shape and is applicable to all known semiconductor wafers. The surface protecting adhesive film for semiconductor wafer according to the present invention is favorably applicable even to a so-called fine-pitched semiconductor wafer in which projections, such as a bump electrode, a defect circuit identification mark or a mixture thereof, each having a height (ha) of from 10 μm to 200 μm are formed on a circuit-forming face (surface) which is likely to generate breakage, stain or the like thereon at the time of reverse side grinding such that a pitch (distance between centers of any two adjacent projections) comes to be from 50 μm to 1000 μm.

A specific pitch between the projections varies depending on types, shapes and heights of the projections, the number of pins of an integrated circuit chip, a packaging method or the like. For example, when a bump electrode (solder, in ball form) having a projection whose height (ha) is 120 μm is formed, the adhesive film according to the present invention is applicable also to a wafer having a pitch of from 150 μm to 1000 μm. Further, for example, when a bump electrode (gold, in a square form having a length of about 45 μm and a width of about 45 μm) having a projection whose height (ha) is 23 μm is formed, the adhesive film is applicable also to a wafer having a pitch of from 50 μm to 500 μm.

The term “bump electrode” used herein is intended to mean an electrode formed together with a circuit on a surface of a semiconductor wafer as an appropriate electrode when a semiconductor chip is packaged by a wireless bonding method such as flip chip packaging or the like. Ordinarily, the semiconductor chip having the bump electrode is directly connected on a packaging substrate via the electrode thereof by a step of reflow, thermal compression bonding or the like whereby the electrode has a height of from about 10 μm to about 200 μm. The semiconductor wafer having this type of the bump electrode is shown in a state in which only an electrode portion of the circuit is protruded (projection) compared with an ordinary one. There are various types of shapes, such as a ball form, a columnar form, a square form, an umbrella form and the like according to methods forming bumps, performance required for chips and the like. As for materials, various types of metals such as solder, gold, silver, copper and the like and alloys thereof are appropriately used in accordance with chip packaging methods or the like.

Further, the term “defect circuit identification mark” is intended to mean a mark which is tagged on a defect circuit for identifying the defect circuit after circuits (chips) formed on a surface of a semiconductor wafer are inspected and sorted out. Ordinarily, the mark has a columnar shape, a conical shape or the like having a diameter of from 0.1 mm to 2 mm and a height of from 10 μm to 100 μm, and is colored by a red dye or the like whereupon a defect circuit identification mark portion is in a state of being protruded (projection) from a surrounding portion of the surface of the semiconductor wafer.

Next, the surface protecting adhesive film for the semiconductor wafer according to the present invention will be described. In the surface protecting adhesive film for semiconductor wafer according to the present invention, at least one intermediate layer and an adhesive layer are formed on one surface of a base film. Of these layers, the adhesive layer (B) is formed in a relatively hard state such that a minimum storage elastic modulus thereof is in a range of from 0.07 MPa to 5 MPa at a temperature of from 50° C. to 100° C. On the other hand, at least one intermediate layer (C) is formed in a relatively soft state such that a storage elastic modulus thereof is from 0.001 MPa to less than 0.07 MPa at 50° C. Further, a surface of the adhesive layer (B) is ordinarily applied with a release film referred to as a separator in a period of from the time just after it is produced to the time it is used to prevent stain thereof taking a possible direct contact with a surface of the semiconductor wafer into consideration.

As the base film for use in the present invention, a film which is produced by molding a synthetic resin in film form is used. The base film may be a single-layer film or a laminate of two or more layers of film. Further, the base film may be produced by processing a thermoplastic resin or by subjecting a thermosetting resin to film-making processing and, then, curing the resultant film. When the base film becomes thin, there is a tendency in which a property of the base film to maintain a feature of the adhesive film becomes deteriorated and, along with such deterioration, workability at the time of handling the adhesive film sometimes becomes deteriorated. On the other hand, when the base film becomes thick, productivity of the base film is affected thereby increasing a production cost. Under these circumstances, thickness of the base film is preferably from 2 μm to 500 am and more preferably from 5 μm to 500 μm.

Examples of raw material resins to be used in base films include polyethylene, polypropylene, polybutene, polymethylpentene, an ethylene-vinyl acetate copolymer, an ethylene-ethylacrylate copolymer, an ethylene-acrylic acid ester-maleic anhydride copolymer, an ethylene-glycidyl methacrylate copolymer, an ethylene-methacrylic acid copolymer, an ionomer resin, an ethylene-propylene copolymer, a thermoplastic elastomer such as a butadiene-type elastomer, a styrene-isoprene-type elastomer or the like, a polystyrene-type resin, polyvinyl chloride resin, a polyvinylidene chloride-type resin, a polyamide-type resin, a polyester such as polyethylene terephthalate, polyethylene naphthalate or the like, polyimide, polyether ether ketone, polycarbonate, polyurethane, an acrylic resin, a fluorocarbon-type resin, a cellulose-type resin and the like. Among these raw material resins, taking protecting performance at the time of subjecting a reverse side of the wafer to grinding processing into consideration, a raw material resin having a Shore hardness D (D hardness by durometer) defined in ASTM-D2240-86 or JIS K7215-1986 of 40 or less is particularly preferable. When these resins are subjected to molding processing to be in film form, a stabilizer, a lubricant, an antioxidant, a pigment, an anti-blocking agent, a plasticizer, an adhesion-imparting agent, a softening agent or the like may optionally be added. When various types of additives such as a stabilizer and the like are added at the time of molding the base film, there is a case in which the additives migrate into the adhesives thereby changing characteristics of the adhesive layer or staining the wafer surface. In this case, a barrier layer is preferably provided between the base film and the adhesive layer for the purpose of preventing various types of additives from migrating into the adhesive layer.

Further, taking into consideration protecting performance of the wafer at a step of executing chemical processing on the reverse side of the wafer which will optionally be conducted after the reverse side of the semiconductor wafer is ground, it is preferable that the base film having an excellent chemical resistance is used. For example, mentioned is a method or the like in which a film having the chemical resistance such as polypropylene, polyethylene terephthalate or the like is laminated on a surface of the base film in a side opposite to a side in which the adhesive layer is provided.

In order to enhance adhesiveness between the base film and the adhesive layer, it is preferable that a corona discharge treatment or a chemical treatment is preliminarily performed on the surface of the base film in a side in which the adhesive layer is provided. Further, for the same purpose, a primer layer may be formed between the base film and the adhesive layer.

The base film to be used for the present invention can appropriately be selected from films produced by known techniques such as a calender method, a T-die extrusion method, a tubular film extrusion method, a cast method and the like, by taking into consideration productivity, thickness accuracy of the film to be obtained or the like.

As release films, mentioned are synthetic resin films such as a polypropylene film, a polyethylene terephthalate film (hereinafter referred to also as PET film) and the like. Optionally, a treatment for facilitating release such as silicone treatment or the like is preferably performed on a surface thereof. Thickness of the release film is ordinarily from about 10 μm to about 2000 μm and preferably from 30 μm to 1000 μm.

In the surface protecting adhesive film for the semiconductor wafer according to the present invention, at least one intermediate layer and an adhesive layer are provided on one surface of the base film. It is permissible that, in the intermediate layer, one layer or two or more layers are formed. Firstly, a first layer of the intermediate layer is formed on one surface of the base film such that it directly contacts the surface. Next, a second layer of the intermediate layer is formed on a surface of the first layer of the intermediate layer, a third layer is formed on a surface of the second layer and other layers are sequentially formed in a same manner as described above until an n th layer of the intermediate layer is formed on an (n−1) th layer. Among these layers of the intermediate layer, at least one layer of the intermediate layer is formed such that it has the above-described storage elastic modulus. The adhesive layer (B) is formed on a surface of the n th layer of the n layers of the intermediate layer thus formed on such one surface of the base film.

The adhesive layer (B) is a layer which directly contacts a surface of the semiconductor wafer at the time it is used and, when prevention of stain on the surface of the semiconductor wafer derived from the adhesive layer (B) is taken into consideration, it is preferable that a minimum value of the storage elastic modulus at a temperature of from 50° C. to 100° C. exists in a specified range. The minimum value (G′ min) of the storage elastic modulus of the adhesive layer (B) at a temperature of from 50° C. to 100° C. gives influence on a stain resistant property against the wafer surface. When the minimum value (G′ min) of the above-described storage elastic modulus is lowered, an adhesive residue is sometimes generated on the wafer surface after the adhesive film is peeled away therefrom. On the other hand, when the storage elastic modulus thereof is unduly high, adhesion to the projection on the wafer surface becomes insufficient and, accordingly, breakage of the wafer or generation of the dimple sometimes occurs. When these features are taken into consideration, the minimum value (G′ min) of the storage elastic modulus of the adhesive layer (B), which is formed on the outermost layer, at a temperature of from 50° C. to 100° C. is preferably from 0.07 MPa to 5 MPa.

Further, when the storage elastic modulus at 25° C. (G′ 25° C.) is lowered, adhesive residue is sometimes generated on the wafer surface after the adhesive film is peeled away therefrom. On the other hand, when it is unduly heightened, adhesiveness thereof is lost and, accordingly, applicability to the wafer surface is deteriorated whereupon application of the adhesive film sometimes becomes difficult. In view of these points, the storage elastic modulus (G′ 25° C.) of the adhesive layer (B) at 25° C. is preferably in a range of from 0.1 MPa to 5 MPa.

Further, when prevention of stain on the wafer surface by the adhesive layer (B) is taken into consideration, it is important to take into consideration a temperature dependence of the storage elastic modulus of the adhesive layer (B). The temperature dependence of the storage elastic modulus of the adhesive layer (B) is deeply related with speed dependency. For these reasons, in a case in which the temperature dependency of the storage elastic modulus of the adhesive layer (B) is high, when peeling conditions such as temperature, speed and the like at the time of peeling the adhesive film away from the wafer surface are fluctuated, or when a shape of the projection on the wafer surface is changed or the like, the adhesive residue on the wafer surface is sometimes generated. In view of these points, a ratio (G′ 25° C./G′ min; hereinafter referred to also as storage elastic modulus ratio) of the storage elastic modulus (G′ 25° C.) of the adhesive layer (B) at 25° C. to the minimum value (G′ min) of the storage elastic modulus thereof at a temperature of from 50° C. to 100° C. is preferably in a range of from 1 to 3. By controlling the storage elastic modulus ratio (G′ 25° C./G′ min) to be within the above-described range, the adhesive layer having a small temperature dependency of the storage elastic modulus can be obtained. As a result, even when the shape of the projection on the wafer surface is changed, or peeling conditions such as a peeling temperature, a peeling speed and the like are fluctuated, the adhesive residue on the wafer surface is not found, and accordingly, prevention of stain can be accomplished.

When an excellent adhesiveness to the wafer surface, an excellent peeling property, a stain resistant property against the wafer surface and the like are taken into consideration, it is preferable that the storage elastic modulus (G′ 25° C.) of the adhesive layer (B) at 25° C. is in a range of from 0.1 MPa to 5 MPa and the corresponding storage elastic modulus ratio (G′ 25° C./G′ min) is in a range of from 1 to 3.

Thickness (tb) of the adhesive layer (B) has an effect on a stain property, an adhesion force and the like against the wafer surface. When the thickness is lowered, stain sometimes remains on the wafer surface due to the adhesive residue. When the thickness is heightened, there is a case in which the adhesion force is increased where upon deterioration of workability at the time of peeling is induced. In view of these features, the thickness (tb) of the adhesive layer (B) is preferably from 1 μm to 50 μm and more preferably from 1 μm to 40 μm. In order to achieve an excellent adhesion to the projection on the wafer surface, a product (tb·G′ min) of the thickness (tb; unit being μm) of the adhesive layer (B) and the minimum value (G′ min) of the storage elastic modulus (G′; unit being MPa) at from 50° C. to 100° C. is preferably in a range of from 0.1 to 50.

The storage elastic modulus of the intermediate layer at 50° C. has an effect on adhesiveness to the surface of the semiconductor wafer. When the storage elastic modulus thereof is high, the intermediate layer becomes hard thereby deteriorating the adhesiveness. For example, when a semiconductor wafer in which projections, such as a bump electrode, a defect circuit identification mark, a mixture thereof or the like, each having a height of from 10 μm to 200 μm, are formed on a circuit-forming surface of the semiconductor wafer at a pitch of from 50 μm to 1000 μm is used, such a tendency is particularly conspicuous. On the other hand, when the storage elastic modulus thereof is unduly low, although the adhesiveness is enhanced, a flowability is increased whereupon it becomes difficult to maintain a shape of the intermediate layer thereby deteriorating a handling property at the time of application or peeling. In view of these features, in regard with at least one layer (C) of the intermediate layer, the storage elastic modulus thereof at 50° C. is preferably 0.001 MPa to less than 0.07 MPa. It is permissible that, in the intermediate layer (C) having such a characteristic, one layer or two or more layers are formed.

When it is intended that the handling property, an interlayer adhesion force of the intermediate layer, an adhesion force between the intermediate layer and the base film or the like is enhanced, the intermediate layer having the storage elastic modulus at 50° C. outside the above-described range may be formed so long as it does not damage the object of the present invention. On this occasion, taking the adhesiveness to the wafer surface into consideration, a total thickness of the intermediate layer having the storage elastic modulus outside the above-described range is preferably 25% or less of a total thickness (tc) of the intermediate layer (C) having the storage elastic modulus within the above-described range.

It is important that, in the intermediate layer, a total thickness (tc) of the intermediate layer (C) having a storage elastic modulus at 50° C. of from 0.001 MPa to less than 0.07 MPa and thickness (tb) of the adhesive layer (B) satisfy the above-described mathematical expression (1). By satisfying the expression, the adhesive film is allowed to be compatible with the projections on the wafer surface thereby enhancing the adhesiveness to the projections. As a result, when the reverse side of the wafer is ground, generation of dimples on the reverse side of the wafer corresponding to the projections is prevented and, accordingly, breakage of the wafer is prevented.

The surface protecting adhesive film for the semiconductor wafer according to the present invention can favorably be used for protecting the surface of the semiconductor wafer having a height of from 10 μm to 200 μm, selected from the group consisting of: a bump electrode and a defect circuit identification mark on a circuit-forming surface thereof and the total thickness (tc, unit: μm) of the intermediate layer (C) and height (ha, unit: μm) of the projection (A) satisfy a relation represented by the following mathematical expression (2).

tc≧ha (2)

By satisfying the above-described mathematical expression (1) and the mathematical expression (2) to be described below at the same time, the above-described effects can more markedly be exerted.

Thickness of each layer of the intermediate layer (C) having the storage elastic modulus within the above-described range is, being in a range which satisfies the above-described conditions, ordinarily from 3 μm to 300 μm and more preferably is appropriately selected from within a range of from 5 μm to 250 μm. When the thickness is unduly large, it sometimes occurs that fabrication of the adhesive film becomes difficult or productivity is affected to increase a production cost. On the other hand, when it is unduly small, adhesiveness to the wafer surface is deteriorated. When these features are taken into consideration, the total thickness (tc) of the intermediate layer (C) having the storage elastic modulus within the above-described range is preferably from 10 μm to 400 μm and more preferably from 10 μm to 300 μm. Further, a comprehensive thickness of the adhesive layer (B) and all of the intermediate layers is preferably from 11 μm to 550 μm.

As for the adhesive layer (B) and the intermediate layer according to the present invention, so long as the above-described conditions are satisfied, a polymer which is a main component in these layers can be selected from the group consisting of known polymers of various types, that is, a natural rubber-type polymer, a synthetic rubber-type polymer, a silicone rubber-type polymer, an acrylic rubber-type polymer and the like. Among these polymers, the acrylic rubber-type polymer is preferable as the primary component when control of physical properties, reproducibility and the like are taken into consideration.

When the polymer is of the acrylic rubber-type, main monomers which constitute the polymer preferably include an acrylic acid alkyl ester, a methacrylic acid alkyl ester and mixtures thereof. Examples of such acrylic acid alkyl esters and methacrylic acid alkyl esters include methyl acrylate, methyl methacrylate, ethyl acrylate, ethyl methacrylate, n-butylacrylate, n-butylmethacrylate, 2-ethylhexylacrylate, 2-ethylhexyl methacrylate, octyl acrylate and the like. These monomers may be used either alone or in mixtures thereof. A quantity of a main monomer to be used is preferably in a range of from 60% by weight to 99% by weight of a total quantity of all monomers which are raw materials of the polymer. By using a mixture of monomers having such compositions, a polymer having at least one of an acrylic acid alkyl ester unit, a methacrylic acid alkyl ester unit and a unit of mixture of these monomers each of which has about the same composition as described above can be obtained.

The polymer may have a functional group which can react with a cross-linking agent. Examples of such functional groups include a hydroxyl group, a carboxyl group, an epoxy group, an amino group and the like. As a method for introducing the functional group which can react with the cross-linking agent into an adhesive polymer, a method of copolymerizing a comonomer having such a functional group at the time of polymerizing a polymer has ordinarily been used.

Examples of comonomers having the above-described functional group include acrylic acid, methacrylic acid, itaconic acid, mesaconic acid, citraconic acid, fumaric acid, maleic acid, an itaconic acid monoalkyl ester, a mesaconic acid monoalkyl ester, a citraconic acid monoalkyl ester, a fumaric acid monoalkyl ester, a maleic acid monoalkyl ester, 2-hydroxyethyl acrylate, 2-hydroxyethyl methacrylate, acrylamide, methacrylamide, tert-butylaminoethyl acrylate, tert-butylaminoethyl methacrylate and the like.

One type of the above-described comonomers may be copolymerized with the above-described main monomer, or two or more types thereof may be copolymerized with the above-described main monomer. A quantity (copolymerization quantity) of the above-described comonomer, which can react with the cross-linking agent, to be used is preferably in a range of from 1% by weight to 40% by weight of a total quantity of all monomers which are raw materials of the adhesive polymer. By using a mixture of monomers having such compositions, a polymer having a comonomer unit which has about the same composition as described above can be obtained.

In the present invention, other than main monomers which constitute the above-described polymers and comonomers having a functional group which can react with a cross-linking agent, a specified comonomer (hereinafter referred to also as polymerizable surfactant) having characteristics of a surfactant may be copolymerized. The polymerizable surfactant not only has a property of copolymerizing with the main monomer or the comonomer but also has an action as a surfactant when emulsion polymerization is conducted. When a polymer which has been emulsion polymerized by using the polymerizable surfactant is used, stain on the wafer surface to be caused by the surfactant is not ordinarily generated. Further, even when a small stain to be caused by the adhesive layer occurs, it is possible to easily remove such stain by rinsing the wafer surface.

Examples of polymerizable surfactants include a surfactant produced by introducing a polymerizable 1-propenyl group in a benzene ring of polyoxyethylene nonylphenyl (available from Dai-ichi Kogyo Seiyaku Co., Ltd.; under the trade name of AQUALON RN-10, AQUALON RN-20, AQUALON RN-30, AQUALON RN-50 or the like), another surfactant produced by introducing a polymerizable 1-propenyl group in a benzene ring of an ammonium salt of a sulfuric acid ester of a polyoxyethylene nonylphenyl ether (available from Dai-ichi Kogyo Seiyaku Co., Ltd.; under the trade name of AQUALON HS-10, AQUALON HS-20 or the like), another surfactant which has a polymerizable double bond in the molecule and is of a sulfosuccinic acid diester type (available from Kao Corporation; under the trade name of Latemul S-120A, Latemul S-180A or the like) and the like. Further, optionally, a monomer having a self-cross-linkable functional group such as acrylic acid glycidyl, methacrylic acid glycidyl, isocyanate ethyl acrylate, isocyanate ethyl methacrylate, 2-(1-aziridinyl)ethyl acrylate, 2-(1-aziridinyl)ethyl methacrylate, or the like, a monomer having a polymerizable double bond such as vinyl acetate, acrylonitrile, styrene or the like, a multifunctional monomer such as divinyl benzene, acrylic acid vinyl, methacrylic acid vinyl, acrylic acid allyl, methacrylic acid allyl or the like may be copolymerized.

As a polymerization reaction mechanism of the polymer, mentioned is a radical polymerization, an anionic polymerization, a cationic polymerization or the like. When a production cost of the polymer, an effect of the functional group of the monomer, an effect of an ion on the semiconductor surface and the like are taken into consideration, it is preferable to perform polymerization by the radical polymerization. When polymerization is performed by a radical polymerization reaction, as a radical polymerization initiator, mentioned is an organic peroxide such as benzoyl peroxide, acetyl peroxide, isobutyryl peroxide, octanoyl peroxide, di-tert-butyl peroxide, di-tert-amyl peroxide or the like, an inorganic peroxide such as ammonium persulfate, potassium persulfate, sodium persulfate or the like, an azo compound such as 2,2′-azobisisobutyronitrile, 2,2′-aziobis-2-methylbutyronitrile, 4,4′-azobis-4-cyanovaleric acid or the like.

Further, when the polymer is polymerized by the radical polymerization reaction, for the purpose of adjusting a molecular weight of the polymer or the like, a chain transfer agent may optionally be added. As such chain transfer agents, illustrated are mercaptans such as an ordinary chain transfer agents, for example, tert-dodecyl mercaptan, n-dodecyl mercaptan and the like. A quantity of the chain transfer agents to be used is in a range of from 0.001 parts by weight to 0.5 parts by weight based on 100 parts by weight, that is, a total quantity, of monomers.

The polymerization method of polymers can appropriately be selected from the known polymerization methods such as an emulsion polymerization method, a suspension polymerization method, a solution polymerization method and the like and used. Particularly, as the polymer for use in the adhesive which constitutes the adhesive layer (B), when it is taken into consideration that the adhesive layer (B) is an adhesive layer which directly contacts the surface of the semiconductor wafer, from the standpoint of prevention of stain on the wafer, it is preferable to adopt the emulsion polymerization method which can obtain a polymer having a high molecular weight.

When the polymer is polymerized by the emulsion polymerization method, among these radical polymerization initiators, a water-soluble inorganic peroxide such as ammonium persulfate, potassium persulfate, sodium persulfate or the like, a water-soluble azo compound having a carboxyl group in the molecule such as 4,4′-azobis-4-cyanovaleric acid or the like is preferable. When the effect of the ion on the surface of the semiconductor wafer is taken into consideration, a ammonium persulfate, azo-compound having a carboxyl group in the molecule such as 4,4′-azobis-4-cyanovaleric acid or the like is more preferable. An azo-compound having a carboxyl group in the molecule such as 4,4′-azobis-4-cyanovaleric acid or the like is particularly preferable.

The polymer which forms the adhesive layer (B) and the intermediate layer used in the invention may be added with a cross-linking agent having two or more cross-linkable functional groups in a molecule. By adding the cross-linking agent having two or more cross-linking reaction-type functional groups in a molecule, the cross-linkable functional group contained in the cross-linkable functional group contained in the polymer are allowed to react with each other, thereby being capable of adjusting a cross-linking density, an adhesion force and cohesion force.

Examples of cross-linking agents include an epoxy-type cross-linking agent such as sorbitol polyglycidyl ether, polyglycerol polyglycidyl ether, pentaerythritol polyglycidyl ether, diglycerol polyglycidyl ether, glycerol polyglycidyl ether, neopentyl glycol diglycidyl ether, resorcin glycidyl ether or the like, an aziridine-type cross-linking agent such as trimethylolpropane-tri-β-aziridinyl propionate, tetramethylolmethane-tri-β-aziridinyl propionate, N,N′-diphenylmethane-4,4′-bis(1-aziridine carboxylamide), N,N′-hexamethylene-1,6-bis(1-aziridine carboxylamide), N,N′-toluene-2,4-bis(1-aziridine carboxylamide), trimethylolpropane-tri-β-(2-methylaziridine) propionate or the like, an isocyanate-type cross-linking agent such as tetramethylene diisocyanate, hexamethylene diisocyanate, a tri adduct of toluene diisocyanate of trimethylolpropane, polyisocyanate or the like. These cross-liking agents may be used either alone or in mixtures thereof.

Further, when the polymer is of an aqueous type such as an aqueous solution, an emulsion in which water is a medium or the like, an isocyanate-type cross-linking agent is fast in a deactivating speed due to a side reaction with water whereupon a cross-linking reaction with the polymer does not sufficiently progress in some cases. Therefore, in such cases, it is preferable that, among the above-described cross-linking agents, an aziridine-type or epoxy-type cross-linking agent is used.

A content of the cross-linking agent having two or more cross-linkable functional groups in one molecule in the present invention is from 0.01 parts by weight to 30 parts by weight and preferably from 0.1 parts by weight to 25 parts by weight based on 100 parts by weight of the polymer. When the content of the cross-linking agent is small, a cohesion force becomes insufficient to sometimes cause stain on the wafer surface. When the content thereof is unduly large, the adhesion force between the adhesive layer and the wafer surface becomes weak whereupon water or grinding dust comes in therebetween during grinding processing to sometimes break the wafer or stain the wafer surface by the grinding dust.

In the polymers which constitute the adhesive layer (B) and the intermediate layer according to the present invention, other than the above-described cross-linking agents having two or more cross-linkable functional groups in a molecule, in order to adjust adhesion characteristics, a tackifier of, for example, a rosin type, terpene resin type or the like, any one of various types of surfactant or the like may appropriately be contained. Further, when the polymer is an emulsion, film-forming agents such as diethylene glycol monobutyl ether or the like may appropriately be contained to such an extent as does not affect an object of the invention.

Next, a controlling method of storage elastic modulus of the adhesive layer (B) and the intermediate layer having the above-described storage elastic modulus will be described. The storage elastic modulus (hereinafter referred to also as G′) is influenced by factors such as (1) a type and quantity of a main monomer to be used which constitutes a polymer, (2) a type and quantity (copolymerized quantity) of a comonomer to be used which has a functional group which can react with across-linking agent, (3) a polymerization method of the polymer and (4) a quantity of the cross-linking agent to be added and the like. Such influence of these factors on the storage elastic modulus will be described below.

Firstly, as for (1) the type and quantity of the main monomer to be used which constitutes the polymer, in a case in which an acrylic acid alkyl ester or a methacrylic acid alkyl ester is used as the main monomer, when any one of acrylic acid alkyl esters each having an alkyl group containing 4 or less carbon atoms such as methyl acrylate, ethyl acrylate, n-butyl acrylate and the like, or any one of methacrylic acid alkyl ethers such as methyl methacrylate, ethyl methacrylate, n-butyl methacrylate, 2-ethylhexyl methacrylate and the like is selected, G′ tends to be high. On the other hand, when any one of acrylic acid alkyl esters each having an alkyl group containing from 5 to 8 carbon atoms such as 2-ethylhexyl acrylate, octyl acrylate and the like is selected, G′ tends to be low. In either case, as the quantity of the main monomer to be used becomes larger, the influence on a value of G′ becomes larger.

Therefore, ordinarily, when the adhesive layer (B) is formed, it is preferable to mainly use any one of the acrylic acid esters each having an alkyl group containing 4 or less carbon atoms or anyone of the methacrylic acid esters. Further, when the intermediate layer (C) is formed, it is preferable to mainly use any one of acrylic acid alkyl esters each having an alkyl group containing from 5 to 8 carbon atoms.

As for (2) the type and quantity (copolymerized quantity) of the comonomer to be used which has the functional group which can react with the cross-linking agent, among such comonomers which are ordinarily used, a comonomer having a carboxyl group such as acrylic acid, methacrylic acid, itaconic acid or the like, or another comonomer having an amide group such as acrylamide, methacrylamide, N-methylolacrylamide or the like, any one of methacrylic acid esters such as glycidyl methacrylate, 2-hydroxyethyl methacrylate and the like is used, G′ ordinarily tends to be high. Such tendency is increased more, as the quantity to be used (copolymerized quantity) becomes larger.

Accordingly, it is ordinarily preferable that, when the adhesive layer (B) is formed, the quantity of the comonomer to be added in which the above-described G′ tends to be high is allowed to be as large as possible within the above-described range, whereas, when the intermediate layer (C) is formed, the quantity of the comonomer to be added is allowed to be as small as possible within the above-described range.

As for (3) the polymerization method of the polymer, when a polymerization method capable of obtaining a polymer having a high molecular weight such as an emulsion polymerization method, a method of performing the polymerization process under a condition of high monomer concentration or the like is particularly used, G′ tends to be high compared with a case in which other methods are used and, accordingly, a tendency of decrease of the storage elastic modulus with temperature becomes small whereupon the storage elastic modulus ratio tends to be small. To contrast, when a polymerization method in which molecular weight is hard to be heightened, such as a method of performing polymerization by adding a chain transfer agent, a method of performing a solution polymerization in a system in which a solvent such as toluene or the like having a chain transfer effect is present in a relatively high concentration or the like is used, G′ tends to be low compared with a case in which other methods are used and, accordingly, the storage elastic modulus ratio tends to be large.

Therefore, ordinarily, when the adhesive layer (B) is formed, it is preferable that the above-described method capable of obtaining a high molecular weigh is adopted. On the other hand, when the intermediate layer (C) is formed, it is preferable that the above-described method in which the molecular weight of the polymer is hard to be heightened.

As for (4) the quantity of the cross-linking agent to be added, there is a tendency in which, when the quantity of the cross-linking agent to be added is small, G′ is high whereupon the storage elastic modulus ratio becomes small, whereas, when the quantity thereof is large, G′ is low whereupon the storage elastic modulus ratio becomes large. However, when the quantity of the cross-linking agent to be added is more than a given required quantity which corresponds to the type and quantity (copolymerized quantity) of the comonomer to be used which has a functional group capable of reacting with the above-described cross-linking agent, there is a tendency in which G′ is decreased in adverse by an influence of a remaining unreacted cross-linking agent to increase the storage elastic modulus ratio.

Accordingly, it is ordinarily preferable that, when the adhesive layer (B) is formed, the quantity of the cross-linking agent to be used is allowed to be relatively large within the above-described range, whereas, when the intermediate layer (C) is formed, the quantity of the cross-linking agent to be used is allowed to be relatively small within the above-described range.

When the adhesive layer (B) and the intermediate layer are formed on one surface of the base film, a method in which the above-described polymer is allowed to be in a form of a solution or an emulsion liquid (hereinafter generally referred to also as coating solution) and, then, the resulting coating solution is coated sequentially with a known method using a coater appropriately selected from the group consisting of a roll coater, a comma coater, a die coater, a Meyer bar coater, a reverse roll coater, a gravure coater and the like, dried and formed can be used. On this occasion, in order to protect the thus-formed intermediate layer or the adhesive layer (B) from stain or the like derived from an environmental factors, a release film is preferably applied on a surface of the thus-formed outermost layer.

Alternatively, a method (hereinafter referred to also as transfer method), in which, on one surface of the release film, the coating solution is applied in accordance with the above-described known method and, then, dried to form the adhesive layer (B) and the intermediate layer and, thereafter, the above-described layers are transferred to the base film by using an ordinary method such as a dry laminate method or the like, may be adopted. When a plurality of layers are laminated by the transfer method, it is permissible that the coating solution is applied on one surface of a release film and dried to form a layer and, then, the thus-formed layer is transferred to the base film and such an operation is repeated plural times, or it is also permissible that, after the adhesive layer (B) and the intermediate layer are formed in order on one surface of the release film and, then, the thus-formed layers are transferred to one surface of the base film at a time.

A drying condition at the time of drying the coating solution is not limited to any particular type but, ordinarily, it is preferable to dry the coating solution at a temperature in a range of from 80° C. to 300° C. for a period of from 10 seconds to 10 minutes. Further, it is more preferable to dry it at a temperature in a range of from 80° C. to 200° C. for a period of from 15 seconds to 8 minutes. In the present invention, in order not only to promote the cross-linking reaction between the cross-linking agent and the polymer to a great extent, but also to attain a sufficient adhesiveness between the adhesive layer (B) and the intermediate layer which are laminated, after the coating solution is completely dried, the surface protecting adhesive film for the semiconductor wafer may be heated at a temperature of from 40° C. to 80° C. for a period of from 5 hours to 300 hours.

As for the adhesion force of the surface protecting adhesive film for the semiconductor wafer according to the present invention, a protective property (prevention of invasion of grinding water, grinding dust, chemicals and the like) of the wafer at the time of a grinding processing, a chemical treatment or the like and peeling workability at the time of peeling the adhesive film away from the wafer surface are taken into consideration, the adhesion force measured on the basis of a method defined in JIS Z0237 using SUS304-BA plate as a substrate to be subjected to adhesion, at a peeling rate of 300 mm/min and a peeling angle of 180° is preferably within a range of from 0.24 N/25 mm to 10.0 N/25 mm. When the adhesion force is low, the grinding water sometimes makes an invasion during the grinding processing or the chemical treatment to cause stain on the wafer surface derived from the grinding dust or the like. When the adhesion force becomes high, the peeling workability is deteriorated to sometimes cause the wafer breakage at the time of peeling the adhesive film away from the wafer surface. Then, the adhesion force is more preferably in a range of from 0.50 N/25 mm to 8.0 N/25 mm.

The surface protecting adhesive film for the semiconductor wafer according to the present invention is produced in accordance with the above-described method. From the standpoint of prevention of stain on the surface of the semiconductor wafer, it is preferable that production environments of all raw materials and other materials such as the base film, the release film, the adhesive and the like, and environments of preparation, storage, coating and drying of the adhesive coating solution are maintained so as to comply with cleanliness of Class 1000 or less defined in the U.S. Federal Standard 209b.

Next, a surface protecting method for the semiconductor wafer according to the present invention will be described. The surface protecting method for the semiconductor wafer according to the present invention is a protecting method of the semiconductor wafer over a series of steps comprising applying the surface protecting adhesive film for the semiconductor wafer on a circuit-forming surface of the semiconductor wafer, grinding a reverse side of the semiconductor wafer and peeling off the surface protecting adhesive film for the semiconductor wafer; on this occasion, the protecting method is characterized by using the above-described surface protecting adhesive film for the semiconductor wafer.

Details thereof will be described below.

Firstly, the release film is peeled away from the adhesive layer (B) of the surface protecting adhesive film for the semiconductor wafer (hereinafter referred to also as adhesive film) to expose a surface of the adhesive layer (B) and, then, the adhesive film is applied to a surface of a semiconductor wafer via the thus-exposed adhesive layer (B). Next, the resulting semiconductor wafer is fixed on a chuck table of a grinding machine or the like via the base film layer of the adhesive film to grind a reverse side of the semiconductor wafer. After such grinding is completed, the adhesive film is peeled away from. In some cases, after such grinding of the reverse side is completed but before the adhesive film is peeled away from, a chemical treatment step such as a chemical etching step, polishing step or the like may be conducted. Further, optionally, after the adhesive film is peeled away from, cleaning processing such as rinsing with water, plasma cleaning or the like may be performed on the surface of the semiconductor wafer.

The protecting method of the semiconductor wafer according to the present invention is favorably applied as a surface protecting method for the semiconductor wafer which has projections such as a bump electrode, a defect circuit identification mark, mixtures thereof and the like, each having a height of from 10 μm to 200 μm.

In operations such as the grinding processing, the chemical treatment and the like on the reverse side of the semiconductor wafer in such a series of steps, the semiconductor wafer, which ordinarily has a thickness of from 500 μm to 1000 μm before being ground, is ground to be ordinarily from 100 μm to 600 μm and sometimes to about 50 μm, depending on the type of the semiconductor wafer and the like. When the thickness of the wafer comes down to be less than a range of from 200 μm to 250 μm, in order to enhance strength of the wafer by removing a damaged layer generated on the reverse side of the wafer by mechanical grinding, a step of executing a chemical treatment on the reverse side is sometimes performed subsequent to a step of grinding the reverse side. The thickness of the semiconductor wafer before being ground is appropriately determined depending on the size, the type and the like of the semiconductor wafer, whereas the thickness thereof after ground is appropriately determined depending on the size of the chip, the type of the circuit and the like.

An operation of applying the adhesive film to the semiconductor wafer is sometimes performed manually but ordinarily by an apparatus referred to as an automatic taping machine to which an adhesive film in a roll state is attached. Examples of such automatic taping machines include ones which are available as Model: ATM-1000B and Model: ATM-1100 from Takatori Corporation, Model: STL series from Teikoku Seiki Kabushiki Kaisha, Model: DR-8500II from Nitto Seiki Inc. and the like.

As for the temperature at the time of applying the adhesive film on the semiconductor wafer, a room temperature of around 25° C. is ordinarily used; however, when the above-described automatic taping machine is provided with a device for elevating the temperature of the wafer before an operation of applying the adhesive film thereon is performed, the adhesive film may first be heated to an appropriate temperature by such a heating device and then applied thereon.

The method of grinding processing on the reverse side of the semiconductor wafer is not particularly limited and a known grinding method such as a through-feed method, an in-feed method or the like can be adopted. A grinding operation is preferably performed while the semiconductor wafer and a whetstone are being watered to cool them. Examples of grinding machines for performing grinding processing on the reverse side of the wafer include ones which are available as Model: DFG-860 from Disco Corporation, as Model: SVG-502MKII8 from Okamoto Machine Tool Works. Ltd., as Model: Polish grinder PG200 from Tokyo Seimitsu Co., Ltd. and the like.

After the grinding processing and the chemical treatment on the reverse side of the wafer are completed, the adhesive film is peeled away from the surface of the wafer. An operation of peeling the adhesive film away from the wafer surface may sometimes be conducted manually, but ordinarily conducted by an apparatus referred to as an automatic detaping machine. Examples of such automatic detaping machines include one which are available as Model: ATRM-2000B and Model: ATRM-2100 from Takatori Corporation, as Model: STP series from Teikoku Seiki Kabushiki Kaisha, as Model: HR-8500II from Nitto Seiki Inc. and the like. Further, as for an adhesive tape referred to as a detaping tape used at the time of peeling off the surface protecting adhesive film for the semiconductor wafer away from the semiconductor wafer surface by the automatic detaping machines, for example, Highland-mark Filament Tape No. 897 available from Sumitomo 3M Limited and the like can be used.

Peeling the surface protecting adhesive film away from the surface of the semiconductor wafer is performed at a room temperature of ordinarily around 25° C.; however, when the above-described automatic detaping machine is provided with a device for elevating the temperature of the wafer before an operation of peeling the adhesive film therefrom is performed, the adhesive film may first be heated to an appropriate temperature (ordinarily from 40° C. to 90° C.) by such a heating device and then peeled therefrom.

### EXAMPLES

The present invention is now more specifically described with reference to preferred embodiments. However, it should be noted that these preferred embodiments should not be interpreted as limiting the present invention in any way. In all of Examples and Comparative Examples to be described below, preparation, coating and drying of a coating solution, grinding of a reverse side of a semiconductor wafer and the like have been performed in an environment in which cleanliness of Class 1000 or less defined in the U.S. Federal Standard No. 209b is maintained. Further, in Examples and Comparative Examples to be described below, adhesion force, storage elastic modulus, and practical performance evaluation have been measured and evaluated in accordance with methods to be described below.

(1) Adhesion Force (N/25 mm)

The adhesive film obtained by each of Examples and Comparative Examples was applied to a surface of a SUS304-BA plate (defined in JIS G4305; length: 20 cm, width: 5 cm) via an outermost layer thereof, namely, the adhesive layer (B), and then it was left to stand for one hour at 23° C. Thereafter, while an edge of a sample was tightly held, the adhesive film was peeled away from the surface of the SUS304-BA plate with a peel angle of 180° at a peel rate of 300 mm/min. Stress at the time of peeling is measured and converted in terms of N/25 mm.

(2) Storage Elastic Modulus (MPa)

Under the same application conditions (thickness, drying temperature, drying time and the like) as those of Example and Comparative example, an adhesive layer or an intermediate layer was prepared, by applying a coating solution onto a PET film (release film) in which one surface thereof was subjected to silicone treatment, and drying them. After the adhesive layer or the intermediate layer was formed, in order to impart the same heat history as that of each of the adhesive layers and the intermediate layers described in Examples and Comparative Examples, the thus-formed adhesive layer or intermediate layer was heated at 60° C. for 48 hours while they are each in a state of a single layer. The resultant layers are overlapped with each other in order to produce a sheet in a film state of the adhesive layer or intermediate layer having a thickness of about 1 mm. A sample in a disc-type shape having a diameter of about 8 mm and a thickness of about 1 mm is collected from the thus-produced sheet in a film state. Storage elastic modulus of this sample is measured at a frequency of 1 rad/sec and in a temperature range of from 25° C. to 100° C. by using a dynamic viscoelasticity measurement apparatus (available from Rheometrics Inc. as Model: RMS-800; using an attachment of parallel plate (parallel disc) type having a diameter of 8 mm). Specifically, the sample is set in the dynamic viscoelasticity measurement apparatus at 25° C. via the above-described attachment of parallel plate type to measure the storage elastic modulus while it is heated from 25° C. up to 100° C. at a heating rate of 3° C./min. After such measurement has been completed, from such a storage elastic modulus-temperature curvature at a temperature range of from 25° C. to 100° C. as obtained, a minimum value (G′ min, MPa) of the storage elastic modulus (G′, MPa) at a temperature of from 50° C. to 100° C., a storage elastic modulus (G′, MPa) at 50° C. or a storage elastic modulus (G′ 25° C., MPa) at 25° C. is optionally adopted.

(3) Practical Performance Evaluation

The surface protecting adhesive film for the semiconductor wafer obtained in each of Examples and Comparative Examples is applied on a surface of a semiconductor silicone wafer (diameter: 200 mm; thickness: 725 μm) having projections on a circuit-forming surface thereof (details are shown in Tables 1 and 2) via the adhesive layer (B) which is the outermost layer thereof and, then, the reverse side of the wafer is subjected to grinding processing by using a grinding apparatus (available from Disco Corporation as Model: DFG860) while the riverse side is being watered to allow a thickness of the wafer to be 150 μm. Grinding processing is performed on 10 pieces of the semiconductor silicone wafers for every adhesive film. After the grinding processing has been completed, in regard to the semiconductor silicone wafers, the reverse side of the wafer which has been subjected to the grinding processing is observed to inspect whether any crack or dimple is generated therein. Further, when the dimple was detected, depth of the dimple is measured by using a contact-type fine contour measuring instrument (available from Kosaka Laboratory Ltd. as Model: ET-30K); on this occasion, when depth of the dimple is less than 2.0 μm, it is within a range causing no practical problem whereupon the wafer is determined as acceptable, while, when even one dimple having a depth of 2.0 μm or more is detected, the related wafer is determined as unacceptable. After crack or dimple is observed, if any crack did not observed on the reverse side of the silicone wafer, the above-described adhesive film is peeled away by using an automatic surface protecting tape peeling machine (available from Nitto Seiki Inc. as Model: HR-8500II, detaping tape used is Highland-make filament tape No. 897 (available from Sumitomo 3M Limited; chuck table temperature: 50° C.). The surface from which the above-described adhesive film was peeled away is enlarged to a range of from 50 times to 1000 times by using an optical microscope (available from Nikon Corporation; under the trade name of OPTIPHOT2) and, then, presence of stain against all chips on the surface of the wafer was observed; on this occasion, when one points or more of stains derived from the adhesive residue were detected, the related chips are counted as “stained chips”°and, then, a stain generating ratio Cr is calculated in accordance with the following expression:

Cr=(C2/C1)×100

Wherein Cr represents stain generating ratio (%); C1 represents the number of observed chips; and C2 represents the number of stained chips.

(4) Preparation of Base Film

An ethylene-vinyl acetate copolymer resin having a Shore D hardness of 35 (available from Du Pont-Mitsui Polychemicals Co., Ltd.; under the trade name of EVAFLEXP-1905 (EV460); vinyl acetate unit content: 19% by weight) was subjected to a T-die extruder to form a film having a thickness of 120 μm. On this occasion, a surface of a side on which an adhesive layer or an intermediate layer will be formed was subjected to corona discharge treatment.

(5) Preparation of Coating Solution

### Preparation Example 1

135 parts by weight of deionized water, 0.5 part by weight of 4,4′-azobis-4-cyanovaleric acid (available from Otsuka Chemical Co., Ltd.; under the trade name of ACVA) as a polymerization initiator, 74.25 parts by weight of butyl acrylate, 13 parts by weight of methyl methacrylate, 9 parts by weight of 2-hydroxyethyl methacrylate, 2 parts by weight of methacrylic acid, one part by weight of acrylamide, 0.75 part by weight of an ammonium salt of sulfuric acid ester of polyoxyethylene nonylphenol ether (average addition of ethylene oxide being about 20 mol) in which a polymerizable 1-propenyl group has been introduced in a benzene ring thereof (available from Dai-ichi Kogyo Seiyaku Co., Ltd.; under the trade name of AQUALON HS-20) as a hydrophilic comonomer were put in a polymerization reactor and, then, the resultant mixture was subjected to an emulsion polymerization at 70° C. for 9 hours while stirring to obtain an acrylic resin-type aqueous emulsion. The thus-obtained aqueous emulsion was neutralized by a 14% by weight aqueous ammonia solution to obtain a polymer emulsion (principal component) having a solid content of 40% by weight. 100 parts by weight of the thus-obtained polymer emulsion (polymer concentration being 40% by weight) was collected and further added with a 14% by weight aqueous ammonia solution to adjust a pH thereof to be 9.3. Thereafter, the thus-pH adjusted polymer emulsion was added with 2.5 parts by weight of an aziridine-type cross-linking agent (available from Nippon Shokubai Co., Ltd.; under the trade name of Chemitight PZ-33) and 5 parts by weight of ethylene glycol monobutyl ether to obtain a coating solution.

### Preparation Example 2

21 parts by weight of 2-ethylhexyl acrylate, 48 parts by weight of ethyl acrylate, 21 parts by weight of methyl acrylate, 9 parts by weight of 2-hydroxyethyl acrylate and 0.5 part by weight of benzoyl peroxide as a polymerization initiator were mixed and, then, the resultant mixture was added into a nitrogen gas-flushed flask containing 55 parts by weight of toluene and 50 parts by weight of ethyl acetate dropwise at 80° C. for 5 hours while stirring and, further, stirred for 5 hours to allow a reaction to proceed among them thereby obtaining an acrylic acid ester copolymer solution. Into the thus-obtained solution, added was 0.2 part by weight of an isocyanate-type cross-linking agent (available from Mitsui Takeda Chemicals, Inc.; under the trade name of ORESTAR P49-75S) based on 100 parts by weight of copolymer (solid content) to obtain a coating solution.

### Preparation Example 3

A coating solution was obtained in a same manner as in Preparation Example 1 except that a quantity of the aziridine-type cross-linking agent added was 1.0 part by weight.

### Preparation Example 4

A coating solution was obtained in a same manner as in Preparation Example 2 except that a quantity of the isocyanate-type cross-linking agent added was 0.4 part by weight.

### Preparation Example 5

A coating solution was obtained in a same manner as in Preparation Example 1 except that an epoxy-type cross-linking agent (available from Nagase Chemical Ltd.; under the trade name of DENACOL EX-614) was used and an added quantity thereof was 1.5 part by weight.

### Preparation Example 6

A coating solution was obtained in a same manner as in Preparation Example 1 except that a quantity of the aziridine-type cross-linking agent added was 4.0 parts by weight.

### Preparation Example 7

135 parts by weight of deionized water, 0.5 part by weight of 4,4′-azobis-4-cyanovaleric acid (available from Otsuka Chemical Co., Ltd.; under the trade name of ACVA) as a polymerization initiator, 94 parts by weight of 2-ethylhexyl acrylate, 3 parts by weight of 2-hydroxyethyl methacrylate, 2 parts by weight of methacrylic acid, one part by weight of acrylamide, 0.1 part by weight of n-dodecyl mercaptan, 0.75 part by weight of an ammonium salt of sulfuric acid ester of polyoxyethylene nonylphenol ether (average addition of ethylene oxide being about 20 mol) in which a polymerizable 1-propenyl group has been introduced in a benzene ring thereof (available from Dai-ichi Kogyo Seiyaku Co., Ltd.; under the trade name of AQUALON HS-20) as a hydrophilic comonomer were put in a polymerization reactor and, then, the resultant mixture was subjected to an emulsion polymerization at 70° C. for 9 hours while stirring to obtain an acrylic resin-type aqueous emulsion. The thus-obtained aqueous emulsion was neutralized by a 14% by weight aqueous ammonia solution to obtain a polymer emulsion (principal component) having a solid content of 40% by weight. 100 parts by weight of the thus-obtained polymer emulsion (polymer concentration being 40% by weight) was collected and further added with a 14% by weight aqueous ammonia solution to adjust a pH thereof to be 9.3. Thereafter, the thus-pH adjusted polymer emulsion was added with 0.5 part by weight of an epoxy-type cross-linking agent (available from Nagase Chemical Ltd.; under the trade name of DENACOL EX-614) and 5 parts by weight of diethylene glycol monobutyl ether to obtain a coating solution.

### Preparation Example 8

A coating solution was obtained in a same manner as in Preparation Example 1 except that a quantity of the aziridine-type cross-linking agent added was 1.6 part by weight.

### Preparation Example 9

A coating solution was obtained in a same manner as in Preparation Example 7 except that a quantity of the epoxy-type cross-linking agent added was 2.0 parts by weight.

### Preparation Example 10

A coating solution was obtained in a same manner as in Preparation Example 1 except that a quantity of the aziridine-type cross-linking agent added was 6.0 parts by weight.

### Preparation Example 11

A coating solution was obtained in a same manner as in Preparation Example 2 except that a quantity of the isocyanate-type cross-linking agent added was 1.5 part by weight.

### Preparation Example 12

135 parts by weight of deionized water, 0.5 part by weight of 4,4′-azobis-4-cyanovaleric acid (available from Otsuka Chemical Co., Ltd.; under the trade name of ACVA) as a polymerization initiator, 55.25 parts by weight of butyl acrylate, 22 parts by weight of methyl methacrylate, 15 parts by weight of 2-hydroxyethyl methacrylate, 6 parts by weight of methacrylic acid, one part by weight of acrylamide, 0.75 part by weight of an ammonium salt of sulfuric acid ester of polyoxyethylene nonylphenol ether (average addition of ethylene oxide being about 20 mol) in which a polymerizable 1-propenyl group has been introduced in a benzene ring thereof (available from Dai-ichi Kogyo Seiyaku Co., Ltd.; under the trade name of AQUALON HS-20) as a hydrophilic comonomer were put in a polymerization reactor and, then, the resultant mixture was subjected to an emulsion polymerization at 70° C. for 9 hours while stirring to obtain an acrylic resin-type aqueous emulsion. The thus-obtained aqueous emulsion was neutralized by a 14% by weight aqueous ammonia solution to obtain a polymer emulsion (principal component) having a solid content of 40% by weight. 100 parts by weight of the thus-obtained polymer emulsion (polymer concentration being 40% by weight) was collected and further added with a 14% by weight aqueous ammonia solution to adjust a pH thereof to be 9.3. Thereafter, the thus-pH adjusted polymer emulsion was added with 3.2 parts by weight of an aziridine-type cross-linking agent (available from Nippon Shokubai Co., Ltd.; under the trade name of Chemitight PZ-33) and 5 parts by weight of ethylene glycol monobutyl ether to obtain a coating solution.

### Example 1

When an adhesive layer (B) and an intermediate layer (C) were laminated with each other, a procedure that, firstly, the intermediate layer (C) was laminated on a surface of a base film in a side which has been subjected to corona discharge treatment and, then, the adhesive layer (B) was laminated on a surface of the thus-obtained intermediate layer (C) in a side opposite to the base film was taken. Namely, on a surface of a PET film (release film), having a thickness of 38 μm, one surface of which has been subjected to silicone treatment (release treatment) in a side thus subjected to the release treatment, the coating solution obtained in Preparation Example 2 was applied by a comma coater and dried at 120° C. for 6 minutes to obtain the intermediate layer (C) having a thickness of 200 μm. On the thus-obtained intermediate layer (C), a surface of the above-described base film having a thickness of 120 μm in a side which has been subjected to corona discharge treatment was laminated by using a dry laminator and, then, pressed to allow the intermediate layer (C) to be transferred to the surface of the base film in the side which has been subjected to corona discharge treatment.

Next, the coating solution obtained in Preparation Example 1 was applied on a polypropylene film (release film; thickness being 50 μm) by using a roll coater and dried at 120° C. for 2 minutes to obtain the adhesive layer (B) having a thickness of 10 μm. A PET film (release film) which has been subjected to silicone treatment was peeled away from the intermediate layer (C) laminated on the above-described base film and, then, on the resultant exposed surface of the intermediate layer (C), the adhesive layer (B) was applied and pressed whereupon the adhesive layer (B) was transferred on the surface of the intermediate layer (C) in the side opposite to the base film to be laminated thereon. The resultant laminate was heated at 60° C. for 48 hours and, then, cooled down to room temperature to obtain a surface protecting adhesive film for a semiconductor wafer.

When storage elastic modulus G′ of the adhesive layer (B) and the intermediate layer (C) was measured in accordance with the above-described method, G′ 25° C. and G′ min of the adhesive layer (B) were 0.7 MPa and 0.3 MPa (100° C.) respectively, and storage elastic modulus ratio thereof G′ 25° C./G′ min calculated by using these measurements was 2.3. Storage elastic modulus G′ (MPa) of the intermediate layer (C) at 50° C. was 0.03 MPa. Further, adhesion force of this adhesive film was 3.75 N/25 mm.

By using the thus-obtained adhesive film, the above-described practical performance evaluation was conducted on a semiconductor silicon wafer (diameter: 200 mm; thickness: 725 μm; chip shape: square of 10.0 mm×10.0 mm; a chip pattern is formed all over a surface of the wafer) in which 1369 (37×37=1369) solder bump electrodes (in ball form), each having an average height of 120 μm (120±15 μm), per chip were provided in an area array-type alignment with a 250 μm pitch. When a reverse side of the wafer after subjected to grinding processing was observed, there was no wafer on which any crack or dimple was generated. On a surface of the wafer from which the adhesive film was peeled away, no visible stain derived from adhesive residue was found. The results are shown in Table 1.

### Example 2

A surface protecting adhesive film for a semiconductor wafer was obtained in a same manner as in Example 1 except that, when the intermediate layer (C) according to Example 1 was formed, the coating solution obtained in Preparation Example 4 was used instead of that obtained in Preparation Example 2 and the thickness of the intermediate layer (C) was 150 μm and, further, when the adhesive layer (B) was formed, the coating solution obtained in Preparation Example 3 was used instead of that obtained in Preparation Example 1 and the thickness of the adhesive layer (B) was 30 μm.

When storage elastic modulus G′ of the adhesive layer (B) and the intermediate layer (C) was measured in accordance with the above-described method, G′ 25° C. and G′ min of the adhesive layer (B) were 0.2 MPa and 0.09 MPa (100° C.) respectively, and storage elastic modulus ratio thereof G′ 25° C./G′ min calculated by using these measurements was 2.2. Storage elastic modulus G′ (MPa) of the intermediate layer (C) at 50° C. was 0.05 MPa. Further, adhesion force of this adhesive film was 5.72 N/25 mm.

By using the thus-obtained adhesive film, the above-described practical performance evaluation was conducted on a semiconductor silicon wafer (diameter: 200 mm; thickness: 725 μm; chip shape: square of 10.0 mm×10.0 mm; a chip pattern is formed all over a surface of the wafer) similar to that used for the practical performance evaluation in Example 1. When a reverse side of the wafer after subjected to grinding processing was observed, there was no wafer on which any crack or dimple was generated. On a surface of the wafer from which the adhesive film was peeled away, no visible stain derived from adhesive residue was found. The results are shown in Table 1.

### Example 3

On a surface of a PET film (release film), having a thickness of 38 μm, one surface of which has been subjected to silicone treatment (release treatment) in a side thus subjected to the release treatment, the coating solution obtained in Preparation Example 2 was applied by a comma coater and dried at 120° C. for 4 minutes to obtain the intermediate layer (C2) having a thickness of 60 μm. On the thus-obtained intermediate layer (C2), a surface of the above-described base film having a thickness of 120 μm in a side which has been subjected to corona discharge treatment was laminated by using a dry laminator and, then, pressed to allow the intermediate layer (C2) to be transferred to the surface of the base film in the side which has been subjected to corona discharge treatment.

Next, the coating solution obtained in Preparation Example 4 was applied on a surface of a PET film (release film), having a thickness of 38 μm, one surface of which has been subjected to silicone treatment (release treatment) in a side thus subjected to the release treatment by a comma coater and dried at 120° C. for 4 minutes to obtain the intermediate layer (Cl) having a thickness of 60 μm. The PET film which has been subjected to silicone treatment was peeled away from the intermediate layer (C2) laminated on the above-described base film and, then, on the resultant exposed surface of the intermediate layer (C2), the intermediate layer (C1) was applied and pressed whereupon the intermediate layer (C1) was transferred on the surface of the intermediate layer (C2) in the side opposite to the base film to be laminated thereon. Further, the coating solution obtained in Preparation Example 5 was applied on a polypropylene film (release film; thickness being 50 μm) by using a roll coater and dried at 120° C. for 2 minutes to obtain the adhesive layer (B) having a thickness of 10 μm. The PET film (release film) which has been subjected to silicone treatment was peeled away from a surface of the intermediate layer (C1) laminated subsequent to the intermediate layer (C2) on the above-described base film and, then, on the resultant exposed surface of the intermediate layer (C1), the adhesive layer (B) was applied and pressed whereupon the adhesive layer (B) was transferred on a surface of the intermediate layer (C1) in the side opposite to the intermediate layer (C2) to be laminated thereon. The resultant laminate was heated at 60° C. for 48 hours and, then, cooled down to room temperature to obtain a surface protecting adhesive film for a semiconductor wafer.

When storage elastic modulus G′ of the adhesive layer (B), the intermediate layer (C1) and the intermediate layer (C2) was measured in accordance with the above-described method, G′ 25° C. and G′ min of the adhesive layer (B) were 0.2 MPa and 0.1 MPa (100° C.) respectively, and storage elastic modulus ratio thereof G′ 25° C./G′ min calculated by using these measurements was 2.0. Storage elastic modulus G′ (MPa) of the intermediate layer (Cl) at 50° C. was 0.05 MPa. Storage elastic modulus G′ (MPa) of the intermediate layer (C2) at 50° C. was 0.03 MPa. Further, adhesion force of this adhesive film was 4.61 N/25 mm.

By using the thus-obtained adhesive film, the above-described practical performance evaluation was conducted on a semiconductor silicon wafer (diameter: 200 mm; thickness: 725 μm; chip shape: square having a side of 10 mm) in which defect circuit identification marks (inkdots), each having a diameter of from 500 μm to 600 μm and a height of from 70 μm to 80 μm were each provided in respective center portions of all chips on a wafer with a space of 10 mm pitch between any two marks. When a reverse side of the wafer after subjected to grinding processing was observed, there was no wafer on which any crack or dimple was generated. On a surface of the wafer from which the adhesive film was peeled away, no visible stain derived from adhesive residue was found. The results are shown in Table 1.

### Example 4

The coating solution obtained in Preparation Example 7 was applied on one surface of a polypropylene film (release film; thickness being 50 μm) by using a roll coater and dried at 120° C. for 4 minutes to obtain an intermediate layer (C) having a thickness of 40 μm. On the thus-obtained intermediate layer (C), a surface of the above-described base film in a side which has been subjected to corona discharge treatment was laminated by using a dry laminator and, then, pressed to allow the intermediate layer (C) to be transferred to the surface of the base film in the side which has been subjected to corona discharge treatment. Next, the coating solution obtained in Preparation Example 6 was applied on a propylene film (release film; thickness being 50 μm) by using a roll coater and dried at 120° C. for 2 minutes to obtain an adhesive layer (B) having a thickness of 10 μm. The polypropylene film (release film) was peeled away from the intermediate layer (C) laminated on the above-described base film and, then, on the resultant exposed surface of the intermediate layer (C), the adhesive layer (B) was applied and, then, pressed whereupon the adhesive layer (B) was transferred on the surface of the intermediate layer (C) in the side opposite to the base film to be laminated thereon. The resultant laminate was heated at 60° C. for 48 hours and, then, cooled down to room temperature to obtain a surface protecting adhesive film for a semiconductor wafer.

When storage elastic modulus G′ of the adhesive layer (B) and the intermediate layer (C) was measured in accordance with the above-described method, G′ 25° C. and G′ min of the adhesive layer (B) were 1.0 MPa and 0.6 MPa (100° C.) respectively, and storage elastic modulus ratio thereof G′ 25C/G′ min calculated by using these measurements was 1.7. Storage elastic modulus G′ (MPa) of the intermediate layer (C) at 50° C. was 0.02 MPa. Further, adhesion force of this adhesive film was 2.25 N/25 mm.

By using the thus-obtained adhesive film, the above-described practical performance evaluation was conducted on a semiconductor silicon wafer (diameter: 200 mm; thickness: 725 μm; chip shape: rectangular of 2.5 mm×10.0 mm; a chip pattern is formed all over a surface of the wafer) in which 328 gold bump (in square form) electrodes, each having an average height of 23 μm (23±3 μm) and a size of 45 μm×45 μm, were provided per chip in a state of peripheral alignment with a 70 μm pitch on a periphery of each chip. When a reverse side of the wafer after subjected to grinding processing was observed, there was no wafer on which any crack or dimple was generated. On a surface of the wafer from which the adhesive film was peeled away, no visible stain derived from adhesive residue was found. The results are shown in Table 1.

### Example 5

A surface protecting adhesive film for a semiconductor wafer was obtained in a same manner as in Example 4 except that, when the intermediate layer (C) according to Example 4 was formed, the coating solution obtained in Preparation Example 9 was used instead of the coating solution obtained in Preparation Example 7 and, when the adhesive layer (B) was formed, the coating solution obtained in Preparation Example 8 instead of the coating solution obtained in Preparation Example 6 was used. When storage elastic modulus G′ of the adhesive layer (B) and the intermediate layer (C) was measured in accordance with the above-described method, G′ 25° C. and G′ min of the adhesive layer (B) were 0.5 MPa and 0.2 MPa (100° C.) respectively, and storage elastic modulus ratio thereof G′ 25° C./G′ min calculated by using these measurements was 2.5. Storage elastic modulus G′ (MPa) of the intermediate layer (C) at 50° C. was 0.04 MPa. Further, adhesion force of this adhesive film was 2.16 N/25 mm.

By using the thus-obtained adhesive film, the above-described practical performance evaluation was conducted in a same manner as in Example 4. When a reverse side of the wafer after subjected to grinding processing was observed, there was no wafer on which any crack or dimple was generated. On a surface of the wafer from which the adhesive film was peeled away, no visible stain derived from adhesive residue was found. The results are shown in Table 2.

### Example 6

A surface protecting adhesive film for a semiconductor wafer was obtained in a same manner as in Example 1 except that, when the adhesive layer (B) according to Example 1 was formed, the thickness of the adhesive layer (B) was allowed to be 30 μm. When storage elastic modulus G′ of the adhesive layer (B) and the intermediate layer (C) was measured in accordance with the above-described method, G′ 25° C. and G′ min of the adhesive layer (B) were 0.7 MPa and 0.3 MPa (100° C.) respectively, and storage elastic modulus ratio thereof G′ 25° C./G′ min calculated by using these measurements was 2.3. Storage elastic modulus G′ (MPa) of the intermediate layer (C) at 50° C. was 0.03 MPa. Further, adhesion force of this adhesive film was 3.89 N/25 mm.

By using the thus-obtained adhesive film, the above-described practical performance evaluation was conducted in a same manner as in Example 1. When a reverse side of the wafer after subjected to grinding processing was observed, there was no wafer on which any crack was generated. Dimples were found on surfaces of two wafers among 10 wafers; on this occasion, when depth of these dimples were measured, each depth of them was less than 2.0 μm (actual measurement of the depth being 1.7 μm) whereupon it was judged as acceptable. On a surface of the wafer from which the adhesive film was peeled away, no visible stain derived from adhesive residue was found. The results are shown in Table 2.

### Example 7

A surface protecting adhesive film for a semiconductor wafer was obtained in a same manner as in Example 1 except that, when the adhesive layer (B) according to Example 1 was formed, the coating solution obtained in Preparation Example 10 was used instead of the coating solution obtained in Preparation Example 1. When storage elastic modulus G′ of the adhesive layer (B) and the intermediate layer (C) was measured in accordance with the above-described method, G′ 25° C. and G′ min of the adhesive layer (B) were 2.2 MPa and 2.0 MPa (100° C.) respectively, and storage elastic modulus ratio thereof G′ 25° C./G′ min calculated by using these measurements was 1.1. Storage elastic modulus G′ (MPa) of the intermediate layer (C) at 50° C. was 0.03 MPa. Further, adhesion force of this adhesive film was 1.12 N/25 mm.

By using the thus-obtained adhesive film, the above-described practical performance evaluation was conducted in a same manner as in Example 1. When a reverse side of the wafer after subjected to grinding processing was observed, there was no wafer on which any crack was generated. Dimples were found on surfaces of three wafers among 10 wafers; on this occasion, when depth of these dimples were measured, each depth of them was less than 2.0 μm (actual measurement of the depth being 1.8 μm) whereupon it was judged as acceptable. On a surface of the wafer from which the adhesive film was peeled away, no visible stain derived from adhesive residue was found. The results are shown in Table 2.

### Comparative Example 1

A surface protecting adhesive film for a semiconductor wafer was obtained in a same manner as in Example 1 except that, when the adhesive layer (B) according to Example 1 was formed, the coating solution obtained in Preparation Example 7 was used instead of the coating solution obtained in Preparation Example 1. When storage elastic modulus G′ of the adhesive layer (B) and the intermediate layer (C) was measured in accordance with the above-described method, G′ 25° C. and G′ min of the adhesive layer (B) were 0.1 MPa and 0.02 MPa (100° C.) respectively, and storage elastic modulus ratio thereof G′ 25° C./G′ min calculated by using these measurements was 5.0. Storage elastic modulus G′ (MPa) of the intermediate layer (C) at 50° C. was 0.03 MPa. Further, adhesion force of this adhesive film was 6.45 N/25 mm. By using the thus-obtained adhesive film, the above-described practical performance evaluation was conducted on a semiconductor silicon wafer similar to that used for the practical performance evaluation in Example 1. When a reverse side of the wafer after subjected to grinding processing was observed, there was no wafer on which any crack or dimple was generated. However, when a surface of the wafer from which the adhesive film was peeled away was observed by an optical microscope, stain derived from adhesive residue was found in 8.7% of chips in number based on the total number of chips. The results are shown in Table 3.

### Comparative Example 2

A surface protecting adhesive film for a semiconductor wafer was obtained in a same manner as in Example 1 except that, when the intermediate layer (C) according to Example 1 was formed, the coating solution obtained in Preparation Example 11 was used instead of the coating solution obtained in Preparation Example 2. When storage elastic modulus G′ of the adhesive layer (B) and the intermediate layer (C) was measured in accordance with the above-described method, G′ 25° C. and G′ min of the adhesive layer (B) were 0.7 MPa and 0.3 MPa (100° C.) respectively, and storage elastic modulus ratio thereof G′ 25° C./G′ min calculated by using these measurements was 2.3. Storage elastic modulus G′ (MPa) of the intermediate layer (C) at 50° C. was 0.09 MPa. Further, adhesion force of this adhesive film was 3.21 N/25 mm. By using the thus-obtained adhesive film, the above-described practical performance evaluation was conducted on a semiconductor silicon wafer similar to that used for the practical performance evaluation in Example 1. When a reverse side of the wafer after subjected to grinding processing was observed, although there was no wafer on which any crack was generated, dimples were found on reverse sides of all of 10 wafers put on evaluation. When depth of these dimples was observed, the depth of dimples of all of 10 wafers was 2.0 μm or more whereupon these wafers were judged as unacceptable. On a surface of the wafer from which the adhesive film was peeled away, no visible stain derived from adhesive residue was found. The results are shown in Table 3.

### Comparative Example 3

A surface protecting adhesive film for a semiconductor wafer was obtained in a same manner as in Example 1 except that, when the intermediate layer (C) according to Example 1 was formed, the thickness of the intermediate layer (C) was allowed to be 40 μm and, when the adhesive layer (B) was formed, the thickness of the adhesive layer (B) was allowed to be 20 μm. G′ 25° C. and G′ min of the adhesive layer (B) were 0.7 MPa and 0.3 MPa (100° C.) respectively, and storage elastic modulus ratio thereof G′ 25° C./G′ min calculated by using these measurements was 2.3. Storage elastic modulus G′ (MPa) of the intermediate layer (C) at 50° C. was 0.03 MPa. Further, adhesion force of this adhesive film was 2.28 N/25 mm. By using the thus-obtained adhesive film, the above-described practical performance evaluation was conducted on a semiconductor silicon wafer similar to that used for the practical performance evaluation in Example 3. When a reverse side of the wafer after subjected to grinding processing was observed, there was no wafer on which any crack was generated. However, dimples were found on reverse sides of 5 wafers out of 10 wafers put on evaluation. When depth of these dimples was measured, the depth of dimples of all of these 5 wafers was 2.0 μm or more whereupon these wafers were judged as unacceptable. On a surface of the wafer from which the adhesive film was peeled away, no visible stain derived from adhesive residue was found. The results are shown in Table 3.

### Comparative Example 4

The coating solution obtained in Preparation Example 7 was applied on one surface of a polypropylene film (release film; thickness being 50 gm) by using a roll coater and dried at 120° C. for 4 minutes to obtain an intermediate layer (C) having a thickness of 40 gm. On the thus-obtained intermediate layer (C), a surface of the above-described base film in a side which has been subjected to corona discharge treatment was laminated by using a dry laminator and, then, pressed to allow the intermediate layer (C) to be transferred to the surface of the base film in the side which has been subjected to corona discharge treatment. Next, on one surface of a PET film (release film), having a thickness of 38 μm, one surface of which has been subjected to silicone treatment (release treatment) in a side thus subjected to the release treatment, the coating solution obtained in Preparation Example 4 was applied by a comma coater and dried at 120° C. for 2 minutes to obtain the adhesive layer (B) having a thickness of 10 μm. The polypropylene film (release film) was peeled away from the intermediate layer (C) laminated on the above-described base film and, then, on the resultant exposed surface of the intermediate layer (C), the adhesive layer (B) was applied and, then, pressed whereupon the adhesive layer (B) was transferred on the surface of the intermediate layer (C) in the side opposite to the base film to be laminated thereon. The resultant laminate was heated at 60° C. for 48 hours and, then, cooled down to room temperature to obtain a surface protecting adhesive film for a semiconductor wafer.

When storage elastic modulus G′ of the adhesive layer (B) and the intermediate layer (C) was measured in accordance with the above-described method, G′ 25‘C and G’ min of the adhesive layer (B) were 0.2 MPa and 0.05 MPa (100° C.) respectively, and storage elastic modulus ratio thereof G′ 25° C./G′ min calculated by using these measurements was 4.0. Storage elastic modulus G′ (MPa) of the intermediate layer (C) at 50° C. was 0.02 MPa. Further, adhesion force of this adhesive film was 3.96 N/25 mm. By using the thus-obtained adhesive film, the above-described practical performance evaluation was conducted on a semiconductor silicon wafer similar to that used for the practical performance evaluation in Example 4. When a reverse side of the wafer after subjected to grinding processing was observed, there was no wafer on which any crack or dimple was generated. However, when a surface of the wafer from which the adhesive film was peeled away was observed by an optical microscope, stain derived from adhesive residue was found in 2.2% of chips in number based on the total number of chips. The results are shown in Table 3.

### Comparative Example 5

A surface protecting adhesive film for a semiconductor wafer was obtained in a same manner as in Example 4 except that, when the intermediate layer (C) according to Example 4 was formed, the coating solution obtained in Preparation Example 9 was used instead of the coating solution obtained in Preparation Example 7 and the thickness of the intermediate layer (C) was allowed to be 25 μm and, when the adhesive layer (B) was formed, the coating solution obtained in Preparation Example 10 was used instead of the coating solution obtained in Preparation Example 6.

When storage elastic modulus G′ of the adhesive layer (B) and the intermediate layer (C) was measured in accordance with the above-described method, G′ 25° C. and G′ min of the adhesive layer (B) were 2.2 MPa and 2.0 MPa (100° C.) respectively, and storage elastic modulus ratio thereof G′ 25° C./G′ min calculated by using these measurements was 1.1. Storage elastic modulus G′ (MPa) of the intermediate layer (C) at 50° C. was 0.04 MPa. Further, adhesion force of this adhesive film was 1.09 N/25 mm. By using the thus-obtained adhesive film, the above-described practical performance evaluation was conducted on a semiconductor silicon wafer similar to that used for the practical performance evaluation in Example 4. When a reverse side of the wafer after subjected to grinding processing was observed, there was no wafer on which any crack was generated. However, dimples were found on reverse sides of 3 wafers out of 10 wafers put on evaluation. When depth of these dimples was measured, the depth of dimples of all of these 3 wafers was 2.0 μm or more whereupon these wafers were judged as unacceptable. On a surface of the wafer from which the adhesive film was peeled away, no visible stain derived from adhesive residue was found. The results are shown in Table 3.

### Comparative Example 6

A surface protecting adhesive film for a semiconductor wafer was obtained in a same manner as in Example 4 except that, when the adhesive layer (B) was formed, the coating solution obtained in Preparation Example 12 was used instead of the coating solution obtained in Preparation Example 6.

When storage elastic modulus G′ of the adhesive layer (B) and the intermediate layer (C) was measured in accordance with the above-described method, G′ 25° C. and G′ min of the adhesive layer (B) were 9.0 MPa and 8.0 MPa (100° C.) respectively, and storage elastic modulus ratio thereof G′ 25° C./G′ min calculated by using these measurements was 1.1. Storage elastic modulus G′ (MPa) of the intermediate layer (C) at 50° C. was 0.02 MPa. Further, adhesion force of this adhesive film was 0.48 N/25 mm. By using the thus-obtained adhesive film, the above-described practical performance evaluation was conducted on a semiconductor silicon wafer similar to that used for the practical performance evaluation in Example 4. When a reverse side of the wafer after subjected to grinding processing was observed, there was no wafer on which any crack was generated. However, dimples were found on reverse sides of all of 10 wafers put on evaluation. When depth of these dimples was measured, the depth of dimples of 2 wafers out of these 10 wafers was less than 2.0 μm (actual measurement being 1.8 μm) whereupon these wafers were judged as acceptable. However, since dimples having a depth of 2.0 μm or more on the remaining 8 wafers were observed whereupon these 8 wafers were judged as unacceptable. On a surface of the wafer from which the adhesive film was peeled away, no visible stain derived from adhesive residue was found. The results are shown in Table 3.

TABLE 1

| | Example 1 | Example 2 | Example 3 | Example 4 |
|---|---|---|---|---|
| Adhesive layer (B) | | | | |
| G′_{25° C.} (MPa) [note 1] | 0.7 | 0.2 | 0.2 | 1.0 |
| G′ₘᵢₙ (MPa) [note 2] | 0.3 | 0.09 | 0.1 | 0.6 |
| G′_{25° C.}/G′ₘᵢₙ | 2.3 | 2.2 | 2.0 | 1.7 |
| Thickness tb (μm) | 10 | 30 | 10 | 10 |
| G′ₘᵢₙ × tb (MPa · μm) | 3.0 | 2.7 | 1.0 | 6.0 |
| Intermediate layer (C1) | | | | |
| G′ (MPa) [note 3] | 0.03 | 0.05 | 0.05 | 0.02 |
| Thickness (μm) | 200 | 150 | 60 | 40 |
| Intermediate layer (C2) | | | | |
| G′ (MPa) [note 3] | — | — | 0.03 | — |
| Thickness (μm) | — | — | 60 | — |
| 3 tb (μm) | 30 | 90 | 30 | 30 |
| tc (μm) | 200 | 150 | 120 | 40 |
| Adhesion force (N/ | 3.75 | 5.72 | 4.61 | 2.25 |
| 25 mm) | | | | |
| Practical performance | | | | |
| evaluation | | | | |
| Detail of projection on | | | | |
| wafer surface | | | | |
| Type | Solder | Solder | Defect | Gold |
| | bump | bump | circuit | bump |
| | electrode | electrode | identifica- | electrode |
| | (ball form) | (ball form) | tion mark | (square |
| | | | | form) |
| Height ha (μm) | 120 ± 15 | 120 ± 15 | 70-80 | 23 ± 3 |
| Pitch (μm) | 250 | 250 | 10000 | 70 |
| Number/chip | 1369 | 1369 | 1 | 328 |
| Shape of chip | 10 × 10 | 10 × 10 | 10 × 10 | 2.5 × 10 |
| | mm | mm | mm | mm |
| Wafer crack during | None | None | None | None |
| grinding | | | | |
| Dimple in reverse side | None | None | None | None |
| after ground | (All | (All | (All | (All |
| | wafers are | wafers are | wafers are | wafers are |
| | accepta- | accepta- | accepta- | accepta- |
| | ble) | ble | ble | ble |
| Stain generation rate | 0 | 0 | 0 | 0 |
| Cr (%) | | | | |

TABLE 2

| | Example 5 | Example 6 | Example 7 |
|---|---|---|---|
| Adhesive layer (B) | | | |
| G′_{25° C.} (MPa) [note 1] | 0.5 | 0.7 | 2.2 |
| G′ₘᵢₙ (MPa) [note 2] | 0.2 | 0.3 | 2.0 |
| G′_{25° C.}/G′ₘᵢₙ | 2.5 | 2.3 | 1.1 |
| Thickness tb (μm) | 10 | 30 | 10 |
| G′ₘᵢₙ × tb (MPa · μm) | 2.0 | 9.0 | 20 |
| Intermediate layer (C1) | | | |
| G′(MPa) [note 3] | 0.04 | 0.03 | 0.03 |
| Thickness (μm) | 40 | 200 | 200 |
| Intermediate layer (C2) | | | |
| G′ (MPa) [note 3] | — | — | — |
| Thickness (μm) | — | — | — |
| 3 tb (μm) | 30 | 90 | 30 |
| tc (μm) | 40 | 200 | 200 |
| Adhesion force (N/25 mm) | 2.16 | 3.89 | 1.12 |
| Practical performance | | | |
| evaluation | | | |
| Detail of projection | | | |
| on wafer surface | | | |
| Type | Gold bump | Solder bump | Solder bump |
| | electrode | electrode | electrode |
| | (square | (ball form) | (ball form) |
| | form) | | |
| Height ha (μm) | 23 ± 3 | 120 ± 15 | 120 ± 15 |
| Pitch (μm) | 70 | 250 | 250 |
| Number/chip | 328 | 1369 | 1369 |
| Shape of chip | 2.5 × 10 mm | 10 × 10 mm | 10 × 10 mm |
| Wafer crack during grinding | None | None | None |
| Dimple in reverse side after | None | Maximum | Maximum |
| ground | (All wafers | 1.7 μm | 1.8 μm |
| | are | (All wafers | (All wafers |
| | acceptable) | are | are |
| | | acceptable) | acceptable) |
| Stain generation rate Cr (%) | 0 | 0 | 0 |

TABLE 3

| | Comparative | Comparative | Comparative | Comparative | Comparative | Comparative |
|---|---|---|---|---|---|---|
| | Example 1 | Example 2 | Example 3 | Example 4 | Example 5 | Example 6 |
| Adhesive layer (B) | | | | | | |
| G′_{25° C.} (MPa) [note 1] | 0.1 | 0.7 | 0.7 | 0.2 | 2.2 | 9.0 |
| G′ₘᵢₙ (MPa) [note 2] | 0.02 | 0.3 | 0.3 | 0.05 | 2.0 | 8.0 |
| G′_{25° C.}/G′ₘᵢₙ | 5.0 | 2.3 | 2.3 | 4.0 | 1.1 | 1.1 |
| Thickness tb (μm) | 10 | 10 | 20 | 10 | 10 | 10 |
| G′ₘᵢₙ × tb (MPa · μm) | 0.2 | 3.0 | 6.0 | 0.5 | 20 | 80 |
| Intermediate layer (C1) | | | | | | |
| G′ (MPa) [note 3] | 0.03 | 0.09 | 0.03 | 0.02 | 0.04 | 0.02 |
| Thickness (μm) | 200 | 200 | 40 | 40 | 25 | 40 |
| Intermediate layer (C2) | | | | | | |
| G′ (MPa) [note 3] | — | — | — | — | — | — |
| Thickness (μm) | — | — | — | — | — | — |
| 3 tb (μm) | 30 | 30 | 60 | 30 | 30 | 30 |
| tc (μm) | 200 | 200 | 40 | 40 | 25 | 40 |
| Adhesion force (N/25 mm) | 6.45 | 3.21 | 2.28 | 3.96 | 1.09 | 0.48 |
| Practical performance evaluation | | | | | | |
| Detail of projection on wafer | | | | | | |
| surface | | | | | | |
| Type | Solder bump | Solder bump | Defect circuit | Gold bump | Gold bump | Gold bump |
| | electrode | electrode | identification | electrode | electrode | electrode |
| | (ball form) | (ball form) | mark | (square form) | (square form) | (square form) |
| Height ha (μm) | 120 ± 15 | 120 ± 15 | 70˜80 | 23 ± 3 | 23 ± 3 | 23 ± 3 |
| Pitch (μm) | 250 | 250 | 10000 | 70 | 70 | 70 |
| Number/chip | 1369 | 1369 | 1 | 328 | 328 | 328 |
| Shape of chip | 10 × 10 mm | 10 × 10 mm | 10 × 10 mm | 2.5 × 10 mm | 2.5 × 10 mm | 2.5 × 10 mm |
| Wafer crack during grinding | None | None | None | None | None | None |
| Dimple in reverse side after | None | None of | 5 wafers | None | 3 wafers | 8 wafers |
| ground | (All wafers are | wafers are | out of 10 are | (All wafers are | out of 10 are | out of 10 are |
| | acceptable) | acceptable | unacceptable | acceptable) | unacceptable | unacceptable |
| Stain generation rate Cr (%) | 8.7 | 0 | 0 | 2.2 | 0 | 0 |

<Brief Explanation for the Tables>
Note 1:
Storage elastic modulus (MPa) at 25° C.
Note 2:
Minimum value (MPa) of storage elastic modulus at from 50° C. to 100° C.
Note 3:
Storage elastic modulus (MPa) at 50° C.

What is claimed is:

1. A surface protecting adhesive film for a semiconductor wafer in which at least one layer of an intermediate layer and an adhesive layer are provided on one surface of a base film, a minimum value (G′ min) of storage elastic modulus of an adhesive layer (B) at from 50° C. to 100° C. is from 0.07 MPa to 5 MPa, storage elastic modulus of at least one layer (C) of the intermediate layer at 50° C. is from 0.001 MPa to less than 0.07 MPa and thickness (tb, unit: μm) of the adhesive layer (B) and total thickness (tc, unit: μm) of the intermediate layer (C) having said storage elastic modulus satisfy a relation represented by the following mathematical expression (1):
tc≧3tb (1)

2. The surface protecting adhesive film for the semiconductor wafer as set forth in claim 1, wherein storage elastic modulus (G′ 25° C.) of the adhesive layer (B) at 25° C. is from 0.1 MPa to 5 MPa and storage elastic modulus ratio (G′ 25° C./G′ min) is in a range of from 1 to 3.

3. The surface protecting adhesive film for the semiconductor wafer as set forth in claim 1, wherein the thickness (tb) of the adhesive layer (B) is from 1 μm to 50 μm, the total thickness (tc) of the intermediate layer (C) is from 10 μm to 400 μm and the total thickness of the adhesive layer (B) and the intermediate layer is from 11 μm to 550 μm.

4. The surface protecting adhesive film for the semiconductor wafer as set forth in claim 1, wherein thickness of the base film is from 2 μm to 500 μm.

5. The surface protecting adhesive film for the semiconductor wafer as set forth in claim 1, wherein the surface protecting adhesive film for the semiconductor wafer is for protecting a surface of a semiconductor wafer having at least one type of a projection (A), having a height of from 10 μm to 200 μm, selected from the group consisting of: a bump electrode and a defect circuit identification mark on a circuit-forming surface thereof and the total thickness (tc, unit: μm) of the intermediate layer (C) and height (ha, unit: μm) of the projection (A) satisfy a relation represented by the following mathematical expression (2):
tc≧ha (2)

6. A protecting method for a semiconductor wafer comprising the steps of:
applying a surface protecting adhesive film for the semiconductor wafer on a circuit-forming surface of the semiconductor wafer;
grinding a reverse side of the semiconductor wafer; and
peeling the surface protecting adhesive film for the semiconductor wafer away,
wherein the surface protecting film for the semiconductor wafer as set forth in claim 1 is used as said surface protecting adhesive film for the semiconductor wafer.
